(19) United States
(12) Patent Application Publication
(10) Pub. No.: US 2005/0195305 A1
(43) Pub. Date: Sep. 8, 2005

(54) Biasing circuits, solid state imaging devices, and methods of manufacturing the same

(76) Inventors: Jeong-ho Lyu, Gyeonggi-do (KR); Jung-hyun Nam, Gyeonggi-do (KR); Jae-seob Roh, Gyeonggi-do (KR)

Correspondence Address: MYERS BIGEL SIBLEY & SAJOVEC, PO BOX 37428, RALEIGH, NC, 27627, US

(21) Appl. No.: 11/063,105

(22) Filed: Feb. 22, 2005

(30) Foreign Application Priority Data
Mar. 5, 2004 (KR) 2004-14955

(51) Int. Cl. H04N 5/335

(52) U.S. Cl. 348/308

(57) ABSTRACT

A biasing circuit for a charge-coupled device (CCD) includes one or more transistors and a nonvolatile memory cell connected in series between a first electric potential node and a second electric potential node and configured to produce a bias voltage at a node between the nonvolatile memory and one of the one or more transistors. The one or more transistors may include one or more transistors coupled in series between a first terminal of the nonvolatile memory cell and the first electric potential node, and one or more transistors coupled in series between a second terminal of the nonvolatile memory cell and the second electric potential node. The nonvolatile memory cell may include a flash memory cell, e.g., a stacked-gate-type flash memory cell and/or a split-gate-type flash memory cell.

### RELATED APPLICATION

This application claims the priority of Korean Patent Application No. 2004-14955, filed on Mar. 5, 2004, in the Korean Intellectual Property Office, the disclosure of which is incorporated herein in its entirety by reference.

### BACKGROUND OF THE INVENTION

The present invention relates to imaging devices and methods of fabrication therefor and, more particularly, to biasing circuits for charge coupled devices (CCDs), imaging circuits including such biasing circuits, and methods of fabrication therefor.

A typical CCD includes a plurality of photoelectric conversion regions, a plurality of vertical charge transmission regions, a horizontal charge transmission region, and a floating diffusion region. The photoelectric conversion regions (e.g., photodiode regions) typically are arranged in a matrix with regular intervals and convert optical signals to electric signals to generate charges. The vertical charge transmission regions typically are formed between the photoelectric conversion regions and transmit the charges generated in the photoelectric conversion regions in a vertical (column) direction by clocking of gates. The horizontal charge transmission region typically transmits the vertically transmitted charges in a horizontal (row) direction. The floating diffusion region senses the transmitted charges and outputs the charges to a peripheral circuit.

CCDs have been widely applied in cameras, camcorders, multimedia, and closed-circuit televisions (CCTVs). In particular, as the size of the CCDs has decreased and the number of pixels in CCDs has increased, the use of CCDs with micro-lenses has increased.

FIG. 1 is a cross-sectional view of a conventional CCD utilizing micro-lenses. A p-type well 2 is formed in an n-type semiconductor substrate 1, and vertical charge transmission regions 4 are formed in the p-type well 2 between photodiode regions 3. A channel stop layer 5 serves as an electric potential barrier between the photodiode regions 3 and the vertical charge transmission regions 4, and polysilicon gate electrodes 7 are formed over the vertical charge transmission regions 4 and are insulated from the vertical charge transmission regions 4 by an insulating layer 6. A metal light-blocking layer 8 is formed on the polysilicon gate electrodes 7 except in the areas overlying the photodiode regions 3. A color filter layer (not shown) and a micro-lens 9 are formed over the photodiode regions 3.

Light incident on the CCD passes through the micro-lens 9 and is focused onto a photodiode region 3. The micro-lens 9 is provided to enhance condensing efficiency. The incident light energy is converted into charge, which is transmitted to an output node by charge transmission devices, such as the vertical charge transmission region 4 and a horizontal charge transmission region (not shown). The image signal charge is output as an electric signal.

A biasing circuit 10 for applying a bias voltage to the semiconductor substrate 1 is disposed outside the CCD array and connected to an n⁺-type region of the semiconductor substrate 1. When an excessive amount of charge is generated in response to a large amount of light falling on the photodiode region 3, the biasing circuit 10 adjusts the substrate bias and lowers a potential well of the photodiode region 3 so that after a certain amount of charge has accumulated, the excess charge is drained toward the semiconductor substrate 1. However, because individual CCDs may differ due to manufacturing processes, it may be necessary to apply a different substrate bias for each CCD produced by a given process.

FIGS. 2 and 3 illustrate conventional biasing circuits for applying a bias voltage. FIG. 2 is a circuit diagram of a biasing circuit in which a substrate bias is controlled using a fuse that is cut by a voltage applied to a pad. Referring to FIG. 2, a power supply voltage VDD is divided by polysilicon resistors 13 disposed between a power supply voltage VDD node and a ground voltage GND node, and connection nodes of the polysilicon resistors 13 are connected to fuses 12. Pads 11 are for opening a fuse. A desired output voltage can be obtained by selectively cutting the fuses 12 connected to the polysilicon resistors 13.

The biasing circuit of FIG. 2 may significantly increase the area occupied by a chip because the circuit includes a relatively large number of resistors and fuses. The circuit of FIG. 2 may also have a relatively large power consumption. Furthermore, restoration of a mistakenly cut fuse may be difficult.

FIG. 3 is a circuit diagram of a biasing circuit using a metal-insulator-semiconductor field effect transistor (MISFET), as proposed in Japanese Patent Laid-open Publication No. 8-32065. Referring to FIG. 3, a power supply voltage VDD is divided by a plurality of MOS transistors 14 and an MISFET 15, which are connected in series between a power supply voltage VDD node and a ground voltage GND node. In this biasing circuit, an output voltage is adjusted by controlling the voltage across the MISFET 15. The voltage across the MISFET 15 is controlled by applying a control bias to an insulating layer of the MISFET 15 via a pad 16, which is formed of oxide-nitride-oxide (ONO) or nitride-oxide (NO). The biasing circuit employs the MOS transistors 14 and the MISFET 15, which are active devices, instead of resistors, which are passive devices. Thus, power consumption can be reduced, and the area occupied by a chip can be reduced as compared with a biasing circuit using resistors and fuses. However, a program operation on this circuit may be inaccurate due to charges injected during a manufacturing process (e.g., a process using plasma) and/or charge injected in the insulating layer that may be trapped and poorly erased. Thus, the MISFET 15 may not have stable characteristics.

FIG. 4 is a cross-sectional view of the floating diffusion region shown in FIG. 1. The CCD includes the floating diffusion region FD and a reset gate RG and a reset drain RD. The floating diffusion region FD is disposed at the rear end of a horizontal charge transmission region (not shown) to convert charges to a voltage, and the reset gate RG and the reset drain RD are provided to reset charges transmitted to the floating diffusion region FD for each pixel. For example, a p-type well 2 may be formed in an n-type semiconductor substrate 1, and a charge transmission channel region 17 of the horizontal charge transmission region may be formed on a predetermined portion of the p-type well 2. A gate insulating layer 18 may be formed on a portion of the charge transmission channel region 17, and the reset gate RG may be formed on the gate insulating layer 18. The floating diffusion region FD and the reset drain RD may be formed on respective sides of the reset gate RG by implanting n-type ion impurities into the charge transmission channel region 17. The floating diffusion region FD accumulates charge transmitted from the horizontal charge transmission region and, when the reset gate RG is turned on, the charge in the floating diffusion region FD is transferred to the reset drain RD.

In this biasing circuit, a bias is applied to the reset gate RG through the RG pad 19, and charge transmitted to the floating diffusion region FD is detected using a sense amplifier 20 connected to the floating diffusion region FD. It is desirable that a detected signal should completely reset (discharge) accumulated charge at the floating diffusion region FD to the reset drain RD to prepare for a next detection. However, the reset operation may be inadequate due to the operating characteristics of the reset transistor. In particular, charge may remain at the diffusion region, causing charge to be mixed and create image noise. When illumination is low, image noise may become significant.

To facilitate reset operation, it is generally desirable to increase the applied reset voltage. Also, as an operating point in the clocking of the reset gate RG varies according to reset voltage, it is typically desirable that a direct current (DC) bias of the reset gate RG in each device be set to a value that takes into account potential irregularity of the reset gate RG.

### SUMMARY OF THE INVENTION

In some embodiments of the present invention, a biasing circuit for a charge-coupled device (CCD) includes one or more transistors and a nonvolatile memory cell connected in series between a first electric potential node and a second electric potential node and configured to produce a bias voltage at a node between the nonvolatile memory and one of the one or more transistors. The one or more transistors may include one or more transistors coupled in series between a first terminal of the nonvolatile memory cell and the first electric potential node, and one or more transistors coupled in series between a second terminal of the nonvolatile memory cell and the second electric potential node.

In some embodiments, the nonvolatile memory cell includes a flash memory cell. For example, the nonvolatile memory cell may include a stacked-gate-type flash memory cell and/or a split-gate-type flash memory cell.

In further embodiments of the present invention, the biasing circuit further includes an input pad coupled to a gate of the nonvolatile memory cell. First and second resistors may be coupled between the input pad and respective ones of the first and second electric potential nodes.

According to additional embodiments of the present invention, a solid state imaging device includes a semiconductor substrate and a plurality of device regions formed on and/or in the semiconductor substrate. The device further includes a biasing circuit coupled to the substrate and/or one of the device regions and operative to apply a bias voltage thereto. The biasing circuit includes one or more transistors and a nonvolatile memory cell connected in series between a first electric potential node and a second electric potential node and configured to produce the bias voltage at a node between the nonvolatile memory and one of the one or more transistors.

In further embodiments of the present invention, a solid state imaging device includes a photoelectric conversion region, a charge transmission region configured to transmit charge from the photoelectric conversion region, a floating diffusion region configured to transfer charge transmitted by the charge transmission region to a peripheral circuit, and a reset gate and a reset drain configured to transfer charge from the floating diffusion region. The device further includes a biasing circuit configured to apply a bias voltage to the reset gate or the reset drain. The biasing circuit includes one or more transistors and a nonvolatile memory cell connected in series between a first electric potential node and a second electric potential node and configured to produce the bias voltage at a node between the nonvolatile memory and one of the one or more transistors.

In some method embodiments of the present invention, solid state imaging devices are fabricated. A gate insulating layer is formed on a semiconductor substrate. A first polysilicon layer is formed on the gate insulating layer. The first polysilicon layer is patterned to form a first polysilicon gate in a device region and a floating gate in a biasing circuit region. An intergate insulating layer is formed on the first polysilicon gate and the floating gate. A second polysilicon layer is formed on the intergate insulating layer, and patterned to form a second polysilicon gate in the device region and to form a control gate and one or more transistor gates in the biasing circuit region, wherein the second polysilicon gate partially overlaps the first polysilicon gate and the control gate partially overlaps the floating gate. Source/drain regions are formed in the substrate on respective sides of the control gate and the one or more transistor gates in the biasing circuit region to form one or more transistors in series with a nonvolatile memory cell. The control gate and the floating gate may have a stacked-gate configuration and/or a split-gate configuration.

### BRIEF DESCRIPTION OF THE DRAWINGS

FIG. 1 is a cross-sectional view of a conventional CCD-type solid state imaging device;

FIG. 2 is a circuit diagram of a conventional biasing circuit used in a biasing circuit of FIG. 1;

FIG. 3 is a circuit diagram of another conventional biasing circuit used in the biasing circuit of FIG. 1;

FIG. 4 is a cross-sectional view of a floating diffusion region included in the device of FIG. 1;

FIG. 5 is a circuit diagram of a biasing circuit according to some embodiments of the present invention;

FIG. 6 is a cross-sectional view of a nonvolatile memory (NVM) cell according to further embodiments of the present invention;

FIG. 7 is a cross-sectional view of an NVM cell according to additional embodiments of the present invention;

FIG. 8 illustrates a solid state imaging device including a biasing circuit according to some embodiments of the present invention;

FIG. 9 illustrates a solid state imaging device including a biasing circuit according to further embodiments of the present invention;

FIG. 10 illustrates a solid state imaging device including a biasing circuit according to still further embodiments of the present invention; and

FIGS. 11 through 17 are cross-sectional views of fabrication products illustrating exemplary operations for manufacturing a solid state imaging device including a biasing circuit according to some embodiments of the present invention.

### DETAILED DESCRIPTION OF EXEMPLARY EMBODIMENTS

The present invention will now be described more fully with reference to the accompanying drawings, in which embodiments of the invention are shown. This invention may, however, be embodied in different forms and should not be construed as being limited to the embodiments set forth herein. Rather, these embodiments are provided so that this disclosure will be thorough and complete, and will fully convey the scope of the invention to those skilled in the art. Like numbers refer to like elements. As used herein the term “and/or” includes any and all combinations of one or more of the associated listed items.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

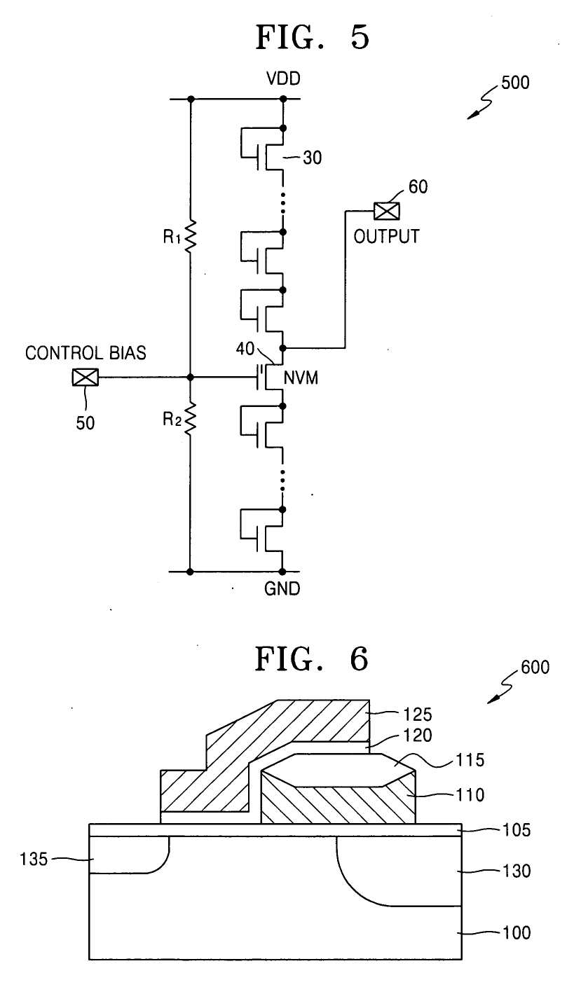

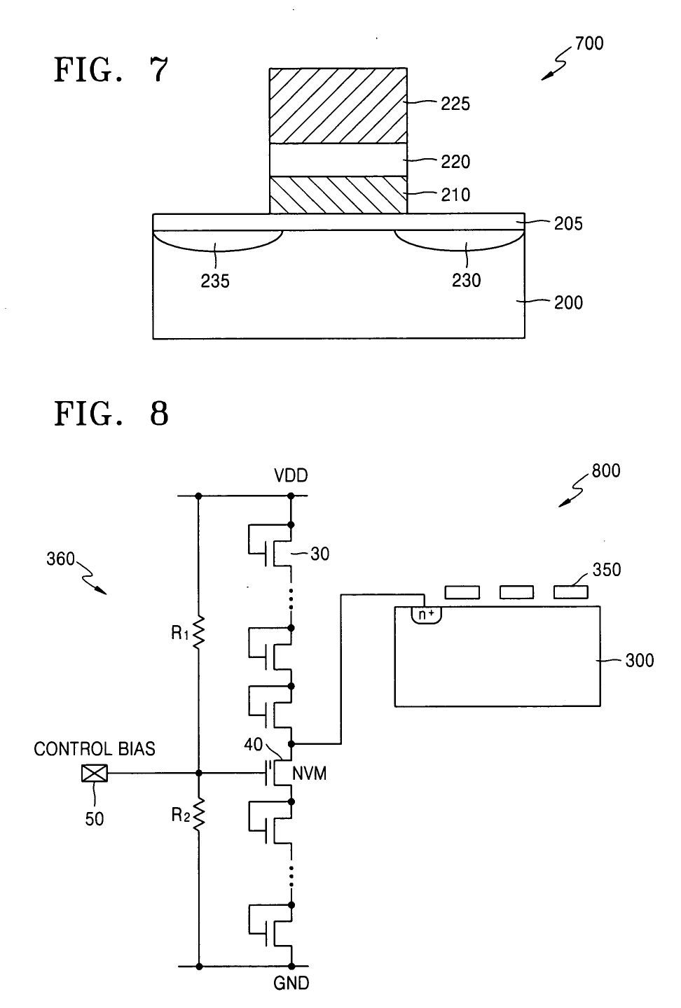

FIG. 5 is a circuit diagram of a biasing circuit 500 according to some embodiments of the present invention. The biasing circuit 500 includes a plurality of transistors 30 and a nonvolatile memory (NVM) cell 40 connected in series between a first electric potential node, e.g., a power supply voltage VDD node, and a second electric potential node, e.g., a ground voltage GND node. A power supply voltage VDD is divided by the transistors 30 and the NVM cell 40, and the biasing circuit 500 produces a bias voltage at a contact point between the transistors 30 and the NVM cell 40 and outputs the bias voltage to an output node 60. The NVM cell 40 may be, for example, a flash memory. As is known, a flash memory can store electric charge in an ONO layer or a floating gate even if its power supply is abruptly interrupted, so that an output voltage can be controlled according to a voltage (threshold voltage) input to a gate of the cell. As will be fully described with reference to FIGS. 6 and 7, the NVM cell 40 preferably includes a flash memory cell including a floating gate and a control gate.

Preferably, the biasing circuit further includes an input pad 50 and first and second resistors R₁ and R₂. A control bias signal is input from the input pad 50, and the first and second resistors R₁ and R₂ are connected to the input pad 50 and can stabilize the control bias signal from the input pad 50. In the NVM cell 40, the output voltage is controlled by injecting or discharging electric charge into or from the floating gate in response to the input signal stabilized by the first and second resistors R₁ and R₂, so that a desired bias voltage is obtained. The transistors 30 are buffer transistors, each of which has its gate connected to its drain, and are connected to a source and a drain of the NVM cell 40.

Generally, an NVM cell (e.g., a flash memory cell) having a structure with multiple gate transistors can control and fix a channel potential using an external bias. Programming is achieved by injecting charge into a floating gate, and charge on the floating gate is erased (discharged) through a tunneling mechanism. In some embodiments of the present invention, an NVM cell having this structure is inserted into a biasing circuit so that a threshold voltage can be controlled using the charge-storing capability of the NVM cell. In particular, it has been demonstrated that an NVM cell having multiple gate transistors may exhibit stable characteristics over a great range of conditions. Accordingly, the biasing circuit of the present invention can output a stable bias voltage.

FIG. 6 is a cross-sectional view of an NVM cell 600 according to some embodiments of the present invention, which may be included in the biasing circuit of FIG. 5. The illustrated NVM cell 600 is a split-gate-type flash memory cell in which a control gate 125 covers a portion of the top surface and one sidewall of a floating gate 110. A source region 130 is disposed in a semiconductor substrate 100 adjacent the floating gate 110. An elliptical oxide layer 115 covers a top surface of the floating gate 10. The sidewall of the floating gate 110 opposite the source region 130 is covered by the control gate 125. The control gate 125 extends from the sidewall of the floating gate 110, covers the top surface of the elliptical oxide layer 115 in one direction, and covers a portion of the semiconductor substrate 100 opposite the source region 130 of the floating gate 110. A drain region 135 is disposed adjacent to the control gate 125 in the semiconductor substrate 100 and the control gate 125 partially overlaps the drain region 135. A gate insulating layer 105 is disposed between the floating gate 110 and the semiconductor substrate 100. A tunnel insulating layer 120 overlaps a portion of the elliptical gate oxide layer 115, and extends from the sidewall of the floating gate 110, between the control gate 125 and the semiconductor substrate 100. Hereinafter, a combination of the elliptical oxide layer 115 and the tunnel insulating layer 120 will be referred to as an intergate insulating layer.

In the split-gate-type flash memory cell 600, the floating gate 110 is separated from the control gate 125 and has an electrically isolated structure. In some embodiments of the present invention, the output voltage of a biasing circuit is controlled by injecting electrons into or emitting electrons from the floating gate 110, i.e., by write and erase operations. In a write operation, a high voltage of about 12 V is applied to the control gate 125, a high voltage of about 7 V is applied to the source 130, and a voltage of 0 V is applied to the drain 135, causing hot electrons to pass through the gate insulating layer 105 on the semiconductor substrate 100 under the floating gate 110 adjacent to the control gate 125 and into the floating gate 110. This increases the threshold voltage and, therefore, reduces the output voltage of the biasing circuit. If a voltage of 15 V or higher is applied to the control gate 125, a high electric field is applied to a tip of the floating gate 110 and electrons in the floating gate 110 are transferred to the control gate 125. This decreases the threshold voltage, and raises the output voltage of the biasing circuit. Injection of electrons into the floating gate 110 is achieved through channel hot electron injection (CHEI), and electrons are emitted by Fowler-Nordheim (F-N) tunneling through the tunnel insulating layer 120 between the floating gate 110 and the control gate 125.

FIG. 7 is a cross-sectional view of an NVM cell 700 that may be used in the biasing circuit of FIG. 5 according to further embodiments of the present invention. The NVM cell 700 is a stacked-gate-type flash memory cell in which the control gate 225 is stacked on the floating gate 210. A gate insulating layer 205 is disposed on a semiconductor substrate 200, and a floating gate 210, an intergate insulating layer 220, and a control gate 225 are stacked thereon. A source 230 and a drain 235 are disposed in the semiconductor substrate 200 on respective sides of the stacked structure.

In this stacked-gate-type flash memory, the control gate 225 is formed on the floating gate 210. Like in the split-gate-type flash memory, the output voltage of the biasing circuit is controlled by injecting electrons into or emitting electrons from the floating gate 210, i.e., by write and erase operations. In a write operation, a high voltage of about 10 V is applied to the control gate 225, a high voltage of about 5 V is applied to the source 230 and the drain 235 floats, and hot electrons are injected from the source 230 through the gate insulating layer 205 into the floating gate 210. Thus, the threshold voltage increases, which reduces the output voltage of the biasing circuit in which the memory cell is used. In an erase operation, if a voltage of about −10 V is applied to the control gate 225, a voltage of about 5 V is applied to the drain 235, and the source 230 floats, electrons in the floating gate 210 are transferred to the drain 235. This reduces the threshold voltage, which increases the output voltage of the biasing circuit. Injection of electrons into the floating gate 210 occurs by hot electron injection, and electrons are transferred from the floating gate 210 by F-N tunneling through the tunnel insulating layer 120.

A biasing circuit as described above with reference to FIGS. 5 through 7 can be integrated with a solid state imaging device and used to apply a bias voltage to a substrate, a reset gate, and/or a reset drain of the solid state imaging device. FIGS. 8 through 10 illustrate solid state imaging devices employing biasing circuits according to various embodiments of the present invention.

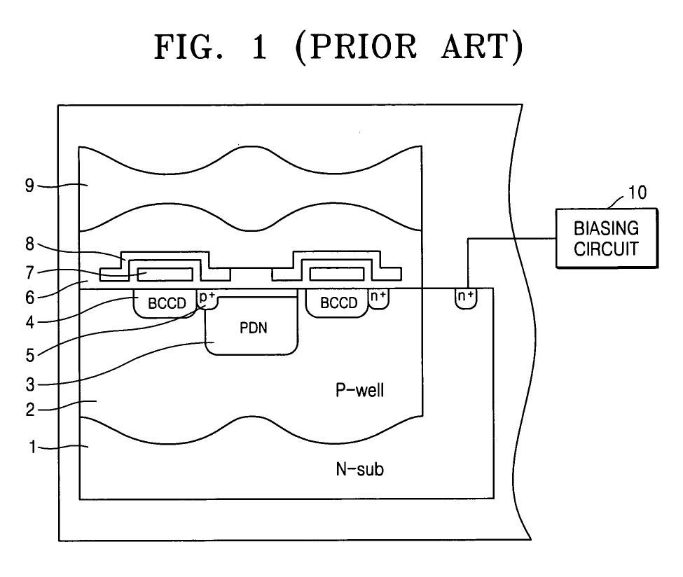

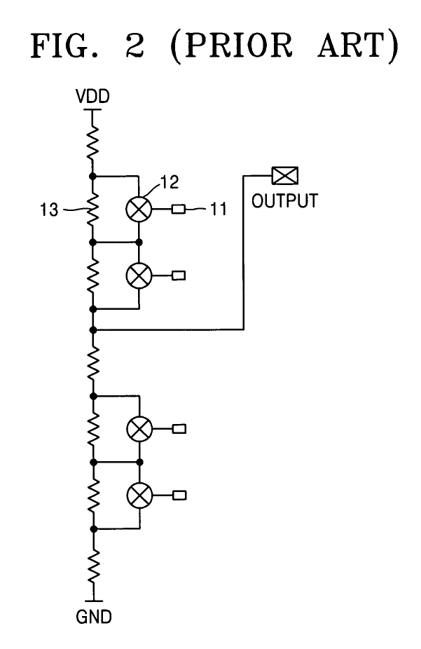

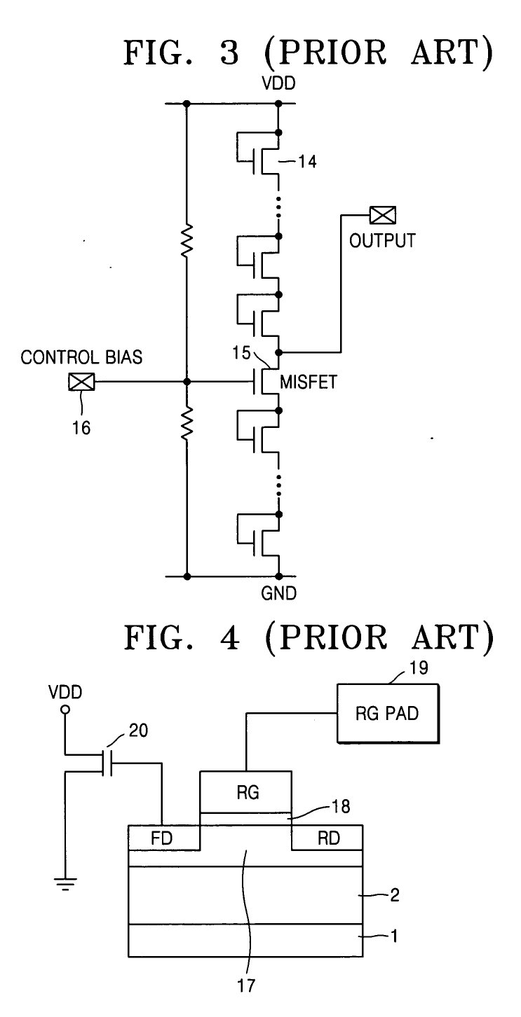

FIG. 8 illustrates a solid state imaging device 800 including a biasing circuit 360 in which a bias voltage is applied to a substrate 300 having a plurality of device regions 350 formed therein. The device regions 350 may, for example, be the same as the elements formed on the substrate 1 as shown in FIG. 1, such as the p-type well 2, the photodiode region 3, the vertical charge transmission region 4, the channel stop layer 5, the insulating layer 6, the polysilicon gate electrode 7, the metal light blocking layer 8, the micro-lens 9, and the like. As described with reference to FIG. 5, the biasing circuit 360 includes one or more transistors 30 and an NVM cell 40, which are connected in series between a first electric potential node VDD and a second electric potential node GND. The biasing circuit 360 produces a bias voltage at a node between the transistors 30 and the NVM cell 40. In the illustrated embodiments, the output node of the biasing circuit 360 is connected to an n⁺-type region of the substrate 300 so as to apply a bias voltage to the substrate 300.

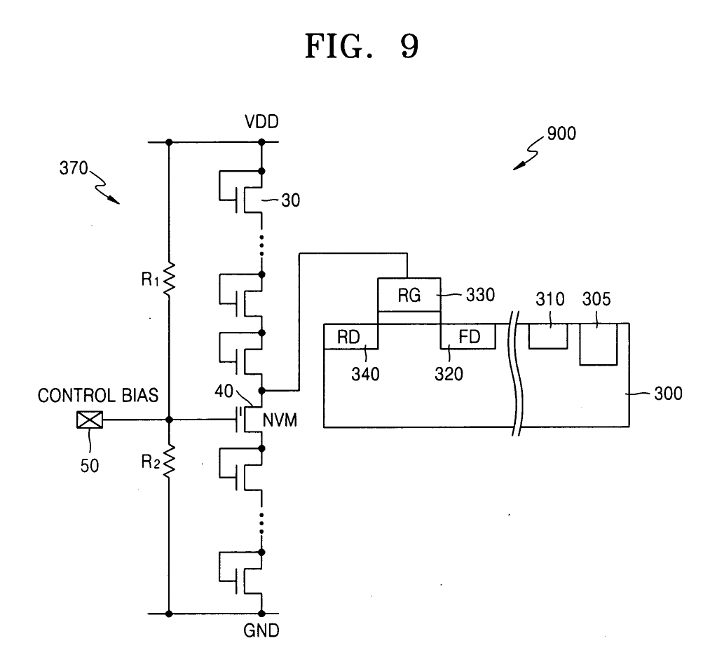

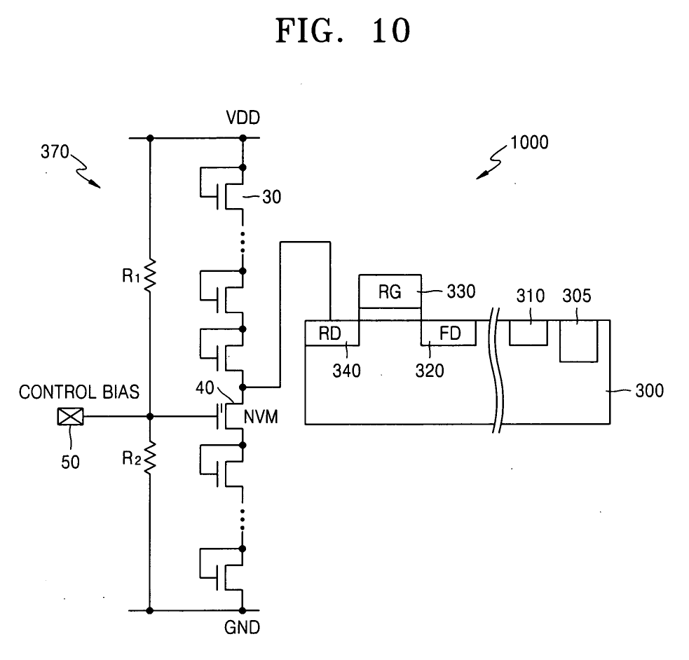

FIGS. 9 and 10 illustrate solid state imaging devices according to further embodiments of the present invention. The embodiments shown in FIGS. 9 and 10 are similar to each other except that a biasing circuit 370 of FIG. 9 applies a bias voltage to a reset gate RG, whereas a biasing circuit 370 of FIG. 10 applies a bias voltage to a reset drain RD. Referring to FIG. 9, a solid state imaging device 900 includes a photoelectric conversion region 305, a charge transmission region 310, a floating diffusion region 320, a reset gate 330, and a reset drain 340, which are disposed on and/or in a substrate 300. The device 900 further includes a biasing circuit 370, which applies a bias voltage to the reset gate 330. The charge transmission region transmits charges produced in the photoelectric conversion region 305, and the floating diffusion region 320 senses the charges transmitted by the charge transmission region 310 and outputs the charges to a peripheral circuit (not shown). The reset gate 330 and the reset drain 340 are provided to reset the charges transmitted to the floating diffusion region 320 for each pixel. As described with reference to FIG. 5, the biasing circuit 370 includes one or more transistors 30 and an NVM cell 40, which are connected in series between a first electric potential node VDD and a second electric potential node GND, and outputs a bias voltage at a node between the transistors 30 and the NVM cell 40. FIG. 10 illustrates an example of a solid state imaging device 1000 in which a biasing circuit 370 applies a bias voltage to the reset drain 340.

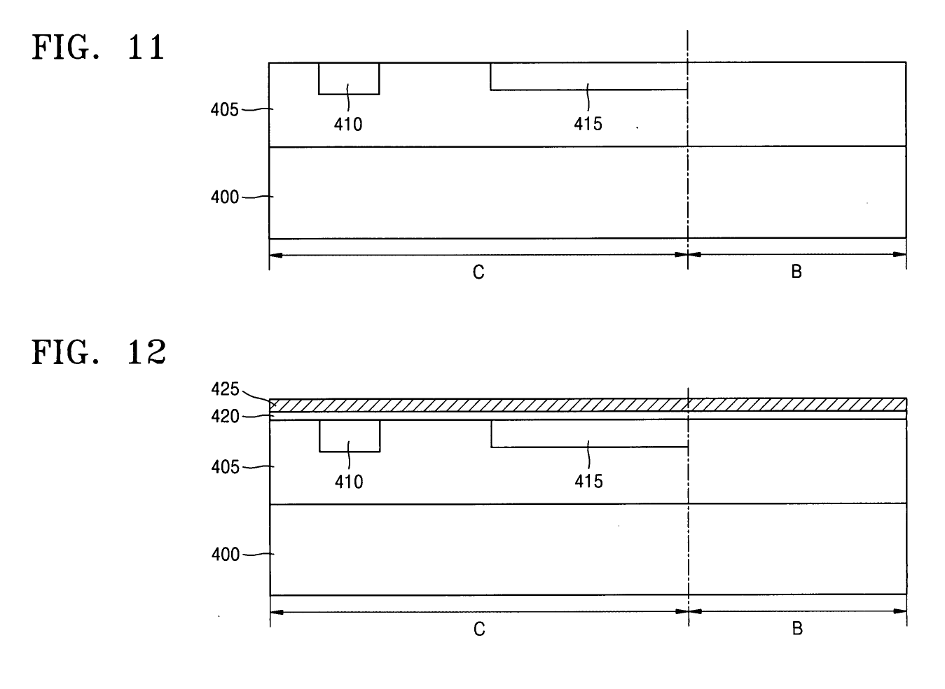

Biasing circuits according to various embodiments of the present invention can be integrated with a solid state imaging device. Hereinafter, exemplary operations for manufacturing a solid state imaging device including a biasing circuit will be described with reference to FIGS. 11 through 17.

Referring to FIG. 11, a device region C and a biasing circuit region B are defined in an n-type semiconductor substrate 400. A p-type well 405 is formed in the substrate 400, and a channel stop layer 410 for isolating pixels from one another is formed in the p-type well 405. Before the p-type well 405 is formed, a cleaning process may be performed and a buffer oxide layer (not shown) may be formed on the substrate 400. An ion implantation mask (not shown) may be formed on the substrate 400, and boron ions doped with a dose of about 2.3E11 ions/cm² and about 1.8 MeV, thereby forming the p-type well 405. If necessary, p-type ions may be doped with a higher dose into a peripheral circuit portion including the biasing circuit region except for the device region C. Thereafter, a CCD channel region 415 including vertical and horizontal charge transmission regions is formed beside the channel stop layer 410 by an ion implantation process that forms charge transmission channels. The CCD channel region 415 may be formed prior to formation of the channel stop layer 410.

Referring to FIG. 12, a gate insulating layer 420 is formed on the surface of the substrate 400 in which the CCD channel region 415 is formed. A portion of the gate insulating layer 420 in the device region C may be an ONO layer, while a portion of the gate insulating layer 420 in the biasing circuit region B may be an oxide layer. For example, a first oxide layer may be formed using thermal oxidation to a thickness of about 300 Å at a temperature of about 900° C. A nitride layer may then be formed to a thickness of about 400 Å using, for example, low pressure chemical vapor deposition (LPCVD). A second oxide layer may be formed by depositing a middle temperature oxide (MTO) to a thickness of about 150 Å and annealing the MTO. After this ONO layer is formed on the entire surface of the substrate 400, the nitride layer and the second oxide layer of the ONO layer may be removed from the biasing circuit region B. A first polysilicon layer 425 is deposited on the gate insulating layer 420. For example, the first polysilicon layer 425 may be formed by LPCVD to a thickness of about 3000 Å.

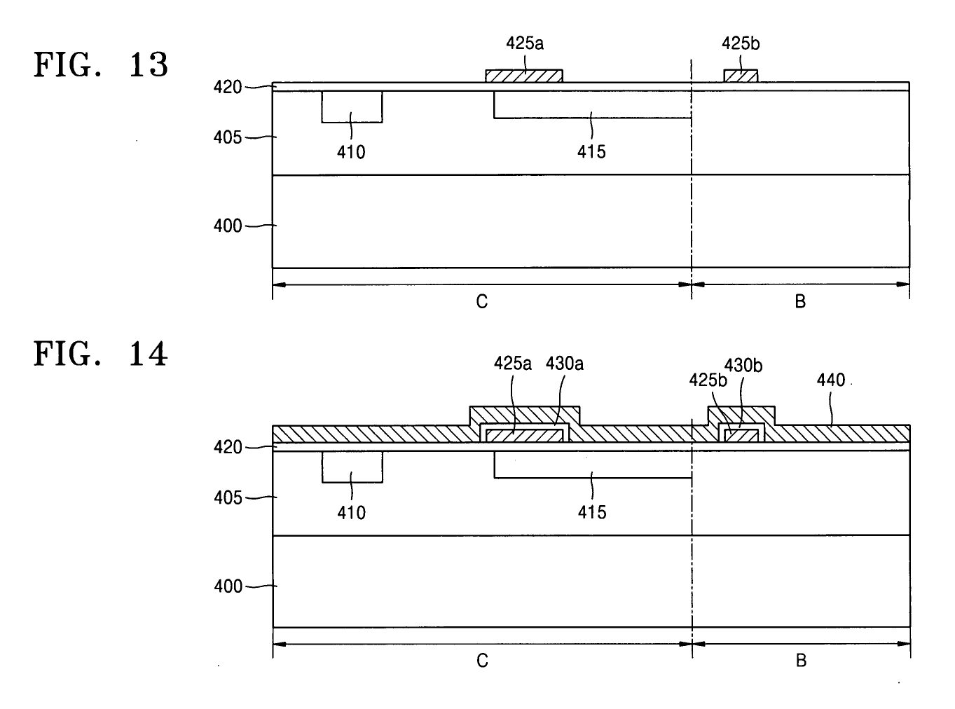

Referring to FIG. 13, the first polysilicon layer 425 is patterned to leave a first polysilicon gate 425a at a certain portion of the CCD channel region 415 of the device region C. Concurrent with the patterning to form the first polysilicon gate 425a, a floating gate 425b of an NVM cell may be formed in the biasing circuit region B. The first polysilicon layer 425 may be patterned using an appropriate etch mask, such as an oxide layer or photoresist layer.

Referring to FIG. 14, intergate insulating layers 430a and 430b for isolating electrodes from one another are formed on the first polysilicon gate 425a and the floating gate 425b. A second polysilicon layer 440 is deposited on the intergate insulating layers 430a and 430b. To form the intergate insulating layers 430a and 430b, a thermal oxide layer may be formed to a thickness of about 300 Å by thermally oxidizing the first polysilicon gate 425a and the floating gate 425b, and an MTO may be deposited thereon to a thickness of about 100 Å. The second polysilicon layer 440 may be formed to a thickness of about 3000 Å.

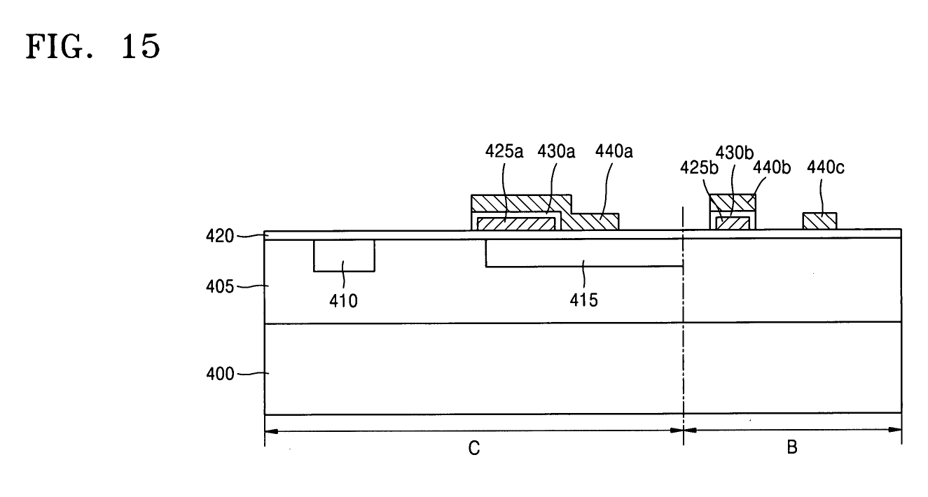

Referring to FIG. 15, the second polysilicon layer 440 is patterned to form a second polysilicon gate 440a that partially overlaps the first polysilicon gate 425a and an adjacent portion of the CCD channel region 415 of the device region C, and a control gate 440b that overlaps the floating gate 425b in the biasing circuit region B. The patterning also forms gates 440c of one or more transistors of the biasing circuit region B.

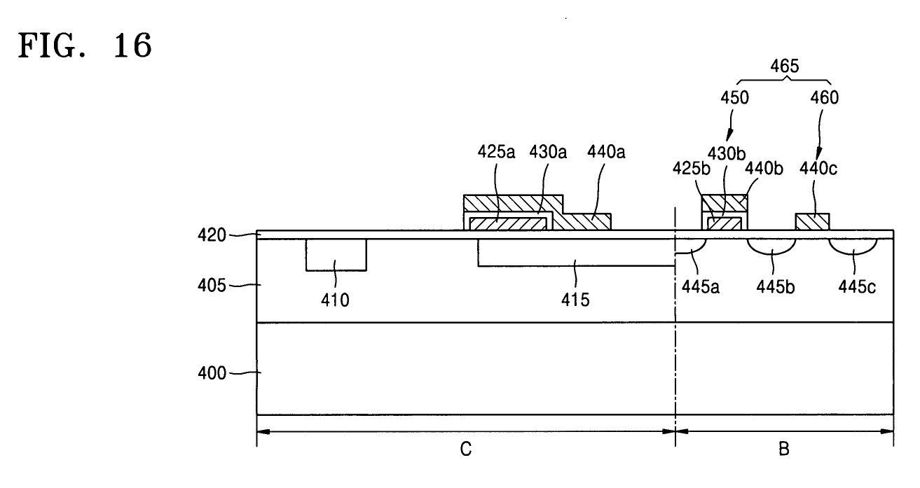

Referring to FIG. 16, a source region 445a and a drain region 445b are formed on respective sides of the control gate 440b by implanting impurity ions into the biasing circuit region B, thus forming an NVM cell 450. The drain region 445b also serves as a source region 445b for a transistor 460 that also includes a drain region 445c, such that the NVM cell 450 is connected in series to the transistor 460 to form a biasing circuit portion 465 that may include other transistors (not shown) that are coupled in series with the NVM cell 450 and the transistor 460. A bias voltage may be produced at a contact point between the transistor 460 and the NVM cell 450.

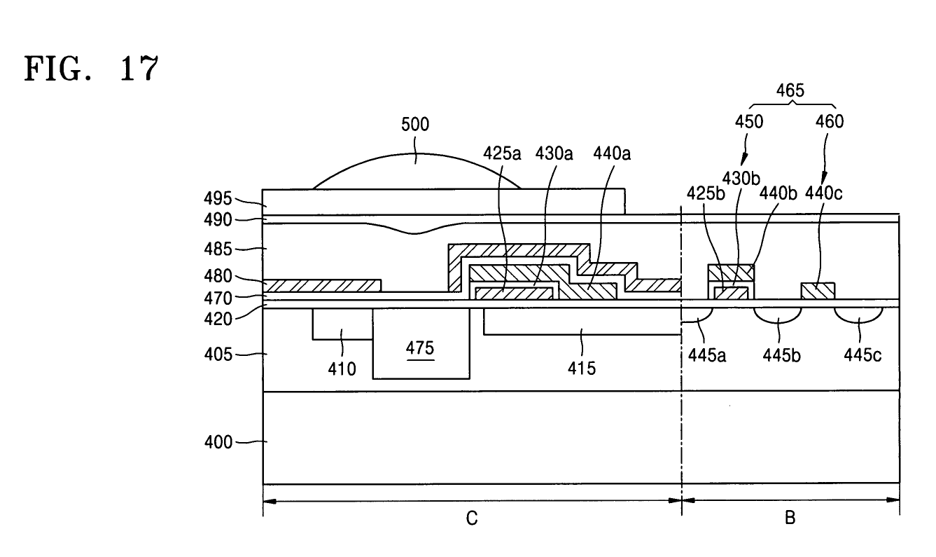

Referring to FIG. 17, an insulating layer 470 is formed on the structure including the second polysilicon gate 440a, and an n-type ion implantation process is performed to form a photodiode region 475, i.e., a photoelectric conversion region. The photodiode region 475 may be formed prior to formation of the source region 445a, the source/drain region 445b and the drain region 445c.

A metal light blocking layer 480 is formed, covering portions of the insulating layer 470 except for a portion overlying the photodiode region 475. The metal light blocking layer 480 may be formed by depositing tungsten to a thickness of about 2000 Å and patterning the same. A passivation layer 485, such as BPSG, is formed, and then a pad open process is performed by selectively removing the passivation layer 485 using a photolithography process. An insulating layer 490 for planarization, such as an oxide layer or a nitride layer, is formed on the passivation layer 485. A color filter layer 495 is formed on a portion of the insulating layer 490 overlying the photodiode region 475. A micro-lens 500 is formed on the color filter layer 495, overlying the photodiode region 475, thus forming a solid state imaging device.

As described above, the first polysilicon gate 425a of the device region C and the floating gate 425b for the NVM cell 450 in the biasing circuit portion 465 may be formed concurrently. In addition, the second polysilicon gate 440a of the device region C and the control gate 440b for the NVM cell 450 in the biasing circuit portion 465 may be formed concurrently. In this manner, a biasing circuit for producing a stable bias voltage can be integrated with a solid state imaging device. It will be appreciated that operations described above for forming a stacked-gate NVM cell in the biasing circuit region B can be modified to form a split-gate NVM cell by forming the control gate 440b such that it overlaps the floating gate 425b and extends onto the adjacent substrate.

Although the present invention has been described with reference to the exemplary embodiments thereof, it will be understood that the invention is not limited to the details thereof. Various substitutions and modifications have been suggested in the foregoing description, and others will occur to those of ordinary skill in the art. Therefore, all such substitutions and modifications are intended to be embraced within the scope of the invention as defined in the appended claims.

1. A biasing circuit for a charge-coupled device (CCD), the biasing circuit comprising:
one or more transistors and a nonvolatile memory cell connected in series between a first electric potential node and a second electric potential node and configured to produce a bias voltage at a node between the nonvolatile memory and one of the one or more transistors.

2. The biasing circuit of claim 1, wherein the one or more transistors comprises:
one or more transistors coupled in series between a first terminal of the nonvolatile memory cell and the first electric potential node; and
one or more transistors coupled in series between a second terminal of the nonvolatile memory cell and the second electric potential node.

3. The biasing circuit of claim 1, wherein the nonvolatile memory cell comprises a flash memory cell.

4. The biasing circuit of claim 3, wherein the bias voltage is dependent on a charge of a floating gate of the nonvolatile memory cell.

5. The biasing circuit of claim 3, wherein the nonvolatile memory cell comprises a stacked-gate-type flash memory cell.

6. The biasing circuit of claim 3, wherein the nonvolatile memory cell comprises a split-gate-type flash memory cell.

7. The biasing circuit of claim 1, further comprising an input pad coupled to a gate of the nonvolatile memory cell.

8. The biasing circuit of claim 7, further comprising first and second resistors coupled between the input pad and respective ones of the first and second electric potential nodes.

9. The biasing circuit of claim 1, wherein the one or more transistors are configured as one or more buffer transistors.

10. A solid state imaging device, comprising:
a semiconductor substrate;
a plurality of device regions formed on and/or in the semiconductor substrate; and
a biasing circuit coupled to the substrate and/or one of the device regions and operative to apply a bias voltage thereto, the biasing circuit comprising one or more transistors and a nonvolatile memory cell connected in series between a first electric potential node and a second electric potential node and configured to produce the bias voltage at a node between the nonvolatile memory and one of the one or more transistors.

11. The device of claim 10, wherein the one or more transistors comprises:
one or more transistors coupled in series between a first terminal of the nonvolatile memory cell and the first electric potential node; and
one or more transistors coupled in series between a second terminal of the nonvolatile memory cell and the second electric potential node.

12. The device of claim 11, wherein the nonvolatile memory cell comprises a flash memory cell.

13. The device of claim 12, wherein the bias voltage is dependent on a charge of a floating gate of the nonvolatile memory cell.

14. The device of claim 12, wherein the nonvolatile memory cell comprises a stacked-gate-type flash memory cell.

15. The device of claim 12, wherein the nonvolatile memory cell comprises a split-gate-type flash memory cell.

16. The device of claim 10, further comprising an input pad coupled to a gate of the nonvolatile memory cell.

17. The device of claim 16, further comprising first and second resistors coupled between the input pad and respective one of the first and second electric potential nodes.

18. The device of claim 10, wherein the one or more transistors are configured as one or more buffer transistors.

19. A solid state imaging device comprising:
a photoelectric conversion region;
a charge transmission region configured to transmit charge from the photoelectric conversion region;
a floating diffusion region configured to transfer charge transmitted by the charge transmission region to a peripheral circuit;
a reset gate and a reset drain configured to transfer charge from the floating diffusion region; and
a biasing circuit configured to apply a bias voltage to the reset gate or the reset drain, the biasing circuit comprising one or more transistors and a nonvolatile memory cell connected in series between a first electric potential node and a second electric potential node and configured to produce the bias voltage at a node between the nonvolatile memory and one of the one or more transistors.

20. The device of claim 19, wherein the one or more transistors comprises:
one or more transistors coupled in series between a first terminal of the nonvolatile memory cell and the first electric potential node; and
one or more transistors coupled in series between a second terminal of the nonvolatile memory cell and the second electric potential node.

21. The device of claim 19, wherein the nonvolatile memory cell comprises a flash memory cell.

22. The device of claim 21, wherein the bias voltage is dependent on a charge of a floating gate of the nonvolatile memory cell.

23. The device of claim 21, wherein the nonvolatile memory cell comprises a stacked-gate-type flash memory cell.

24. The device of claim 21, wherein the nonvolatile memory cell comprises a split-gate-type flash memory cell.

25. The device of claim 19, further comprising an input pad coupled to a gate of the nonvolatile memory cell.

26. The device of claim 25, further comprising first and second resistors coupled between the input pad and respective one of the first and second electric potential nodes.

27. The device of claim 19, wherein the one or more transistors are configured as one or more buffer transistors.

28. A method of manufacturing a solid state imaging device, the method comprising:
forming a gate insulating layer on a semiconductor substrate;
forming a first polysilicon layer on the gate insulating layer;
patterning the first polysilicon layer to form a first polysilicon gate in a device region and a floating gate in a biasing circuit region;
forming an intergate insulating layer on the first polysilicon gate and the floating gate;
forming a second polysilicon layer on the intergate insulating layer;
pattering the second polysilicon layer to form a second polysilicon gate in the device region and to form a control gate and one or more transistor gates in the biasing circuit region, wherein the second polysilicon gate partially overlaps the first polysilicon gate and the control gate partially overlaps the floating gate; and
forming source/drain regions in the substrate on respective sides of the control gate and the one or more transistor gates in the biasing circuit region to form one or more transistors in series with a nonvolatile memory cell.

29. The method of claim 29, wherein the control gate and the floating gate have a stacked-gate configuration.

30. The method of claim 28, wherein the control gate and the floating gate have a split-gate configuration.

31. The method of claim 28, wherein the semiconductor substrate is an n-type substrate, and wherein the method further comprises:
forming a p-type well in the n-type substrate;
forming a channel stop layer on the p-type well;
forming a charge transmission region adjacent the channel stop layer;
forming an insulating layer on the second polysilicon gate;
forming a photodiode region in the device region;
forming a metal light blocking layer on the insulating layer except for a portion overlying the photodiode region;
forming a passivation layer on the metal light blocking layer;
forming a planarizing insulating layer on the passivation layer;
forming a color filter layer on a portion of the planarizing insulating layer overlying the photodiode region; and
forming a micro-lens on the color filter layer and overlying the photodiode region.
